(19) United States
(12) Patent Application Publication
(10) Pub. No.: US 2011/0294308 A1
(43) Pub. Date: Dec. 1, 2011

(54) SUBSTRATE AND IC SOCKET

(75) Inventors: Naoki KUWATA, Kawasaki (JP); Tadashi Ikeuchi, Kawasaki (JP); Takatoshi Yagisawa, Kawasaki (JP)

(73) Assignee: FUJITSU LIMITED, Kawasaki-shi (JP)

(21) Appl. No.: 13/115,322

(22) Filed: May 25, 2011

(30) Foreign Application Priority Data
May 28, 2010 (JP) 2010-122864

(51) Int. Cl. H01R 12/70; H05K 1/00

(52) U.S. Cl. 439/55; 439/525

(57) ABSTRACT

There is provided a substrate that includes a base substrate, a socket that has a step where the step has a first surface and a second surface, the socket being electrically coupled with the base substrate at the first surface; and a connection substrate that is disposed between the second surface and the base substrate, where the connection substrate is electrically coupled with the socket at the second surface.

### CROSS-REFERENCE TO RELATED APPLICATION

This application is based upon and claims the benefit of priority of the prior Japanese Patent Application No. 2010-122864, filed on May 28, 2010 the entire contents of which are incorporated herein by reference.

### FIELD

The embodiments discussed herein are related to a substrate and an IC socket.

### BACKGROUND

Server systems have required an improvement in increasing transmission rate for interfaces used to connect peripheral circuits with a central processing unit or units (CPU or CPUs) together with demand for an increased processing speed. However, when a signal in electric form transmits between the peripheral circuits and the CPU, the transmission rate or a transmission range will be limited owing to the deterioration of waveforms caused by the transmission lines, connectors, and the like on printed circuit substrates which provided therebetween. For improvement in these problems, optical interconnection technology has been introduced in the transmission of signals in the server systems. The optical interconnection technology is a way of connecting a path for optical signal which is converted from responsive electric signal by an optical module.

FIG. 1 illustrates an example of application of the optical interconnection technology to a substrate which includes an IC for transmitting electric signal and an optical module for converting the electric signals to optical signals to be sent to a periphery circuit. Electric signals are transmitted from an IC 11 such as a CPU including an interface operable at high speed so as to respond to high speed data processing of electric signals. The electric signals is electrically transferred to a vertical cavity surface emitting laser (VCSEL) 18 mounted on a substrate 16 to be converted resultantly to optical signals. The electric signals from the IC 11 propagates to the VCSEL 18 through a land grid array (LGA) type IC package 12, an IC socket 13, a substrate 14, a socket 15, a substrate 16, and a driver IC 17. The IC package 12 electrically connects and secures the IC 11 to IC socket 13 mounded on the substrate 14 which also has electrical paths for transferring the electric signals from the IC socket 13 to the socket 15. The electric signals further transfer to the driver IC 17 via the substrate 16. The electric signals are amplified by the driver IC 17 and applied to the VCSEL 18, which are disposed in an optical module 19 are disposed in an optical module 19.

An example of electrical socket for a device such as an IC is disclosed in Japanese Laid-open Patent Publication No. 7-130438 to improve an electrical characteristics of the device.

### SUMMARY

According to an aspect of the invention, a substrate includes a base substrate, a socket that has a step, the step having a first surface and a second surface, the socket being electrically coupled with the base substrate at the first surface; and a connection substrate disposed between the second surface and the base substrate, the connection substrate being electrically coupled with the socket at the second surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an existing example;

FIG. 2 is a diagram illustrating a whole configuration of a substrate according to an embodiment of the present invention;

FIG. 3 is a diagram illustrating a magnified view of a cross section of a first embodiment;

FIG. 4 is a diagram illustrating a perspective view of an example of a flexible cable used in the first embodiment;

FIG. 5 is a diagram illustrating a magnified view of a cross section of a second embodiment; and

FIG. 6 is a diagram illustrating a magnified view of a cross section of a third embodiment.

### DESCRIPTION OF EMBODIMENTS

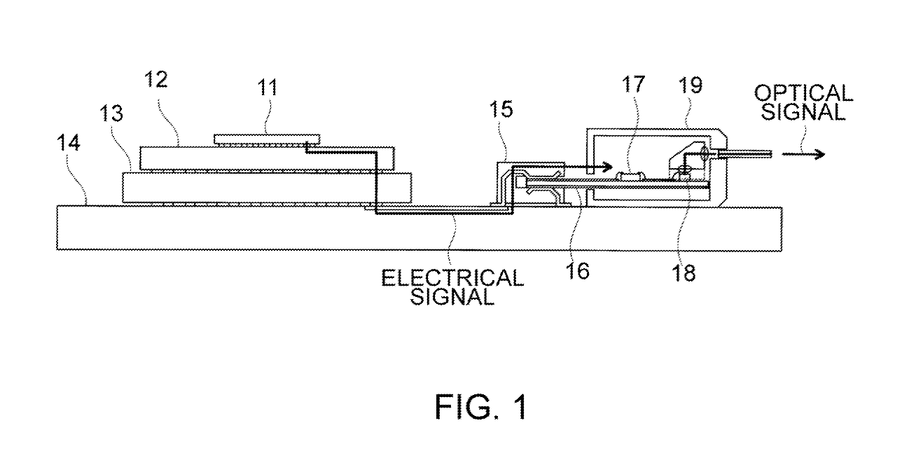

When transmitting a high transmission rate electric signal having a transmission rate exceeding 20 Gb/s, for example, it is necessary to form impedance matched transmission lines. When there is an impedance mismatch, a signal is reflected, resulting in deterioration of the signal. In FIG. 1, there are many connection portions, for example, between the IC socket 13 and the substrate 14, between the substrate 14 and the socket 15, and between the socket 15 and the substrate 16, and hence, impedance mismatching may occur at the connection portions, resulting in deterioration of a signal. In addition, a printed circuit substrate having high-frequency characteristics inferior to those of the substrate 16 is generally used as the substrate 14 owing to cost, for example. Hence in FIG. 1, the waveform of the electric signal of the IC 11, which passes through a transmission line on the substrate 14, deteriorates.

Further, in FIG. 1, the IC socket 13 and the socket 15 for the optical module 19 are mounted on the substrate 14. This results in a problem in that a necessary mounting space increases.

It is an object of the present application to provide a substrate and an IC socket which allow the number of connection portions to be decreased, allow an IC to be connected to the substrate without deterioration of the high-frequency characteristics, and allow a mounting space to be reduced.

A substrate disclosed in the present application is a substrate having an IC package and an IC socket on which the IC package is mounted. The IC socket includes a step formed of a first surface and a second surface facing the substrate. Another substrate is provided in such a manner as to be sandwiched between the second surface and the substrate. The IC socket is connected to the other substrate at the second surface, and the IC socket is connected to the substrate at the first surface.

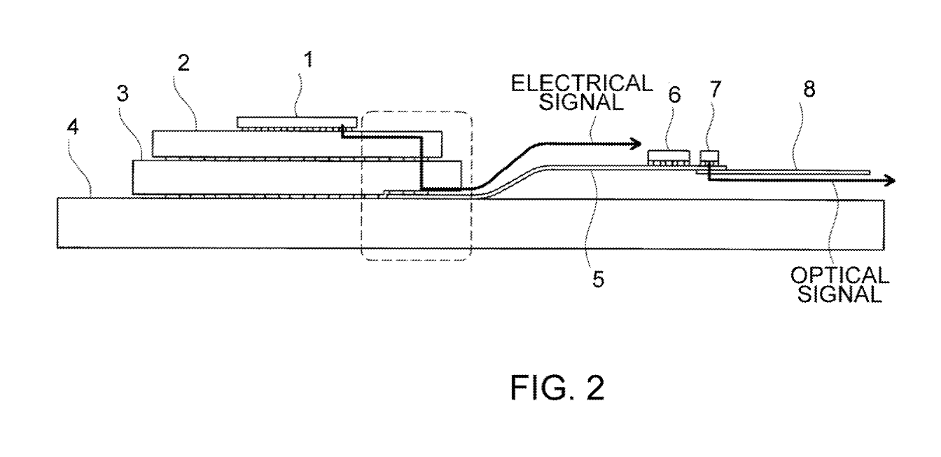

FIG. 2 illustrates the whole configuration of a substrate including an exemplary embodiment. An IC 1 is mounted on the upper surface of an IC socket 3 using, for example, an LGA IC package 2. The IC socket 3 has a step having a higher and lower surfaces between which the level difference is corresponding to the thickness of a flexible cable 5, provided on the lower surface of the IC socket 3. The IC socket 3 has also pins in contact with a substrate 4, and pins in contact with the flexible cable 5. Thereby, the IC socket 3 connects the IC package 2 to both the substrate 4 and the flexible cable 5. The substrate 4 is, for example, a glass-epoxy printed circuit substrate. The flexible cable 5 is a flexible substrate made of a material having good high-frequency characteristics, and has a driver IC 6, a VCSEL 7, and the like mounted thereon.

By employing the configuration described above, an electric signal generated in IC 1 output from the IC package 2 is transmitted over the flexible cable 5 through the IC socket 3. The electric signal from the IC 1 is amplified by the driver IC 6, converted into an optical signal by the VCSEL 7, and transmitted through an optical waveguide 8. Accordingly, the signals from the optical waveguide 8 may be input to the IC 1 through the path described above.

Thus, in the present embodiment, the electric signal generated in the IC 1 output from the IC package 2 is transmitted over the flexible cable 5 having good high-frequency characteristics without passing through the substrate 4. Similarly, the IC 1 may receive the signals from the driver IC 6 with the flexible cable 5. Thus, compared with the existing example illustrated in FIG. 1, the number of connection portions is decreased and the IC 1 may be connected to the flexible cable 5 without deterioration or with little deterioration of the high-frequency characteristics. Hence, the output and the received waveforms of the signal of the IC 1 are prevented from deteriorating.

In the existing example illustrated in FIG. 1, two sockets, that is the IC socket 13 and the socket 15, are used. In the present embodiment, however, using only the IC socket 3, the IC package 2 is connected to the substrate 4 and the flexible cable 5. This configuration of the present embodiment allows the mounting space on the substrate 4 to be reduced. Hence, cost reduction is also realized owing to a reduction in the area of the substrate and the number of components.

Further, since the IC socket 3 is employed in the configuration of the present embodiment, the configuration may provide high flexibility for combining the IC 1 with the optical module. Since components may be arranged below the flexible cable 5, thereby the flexibility may be provided for arranging components.

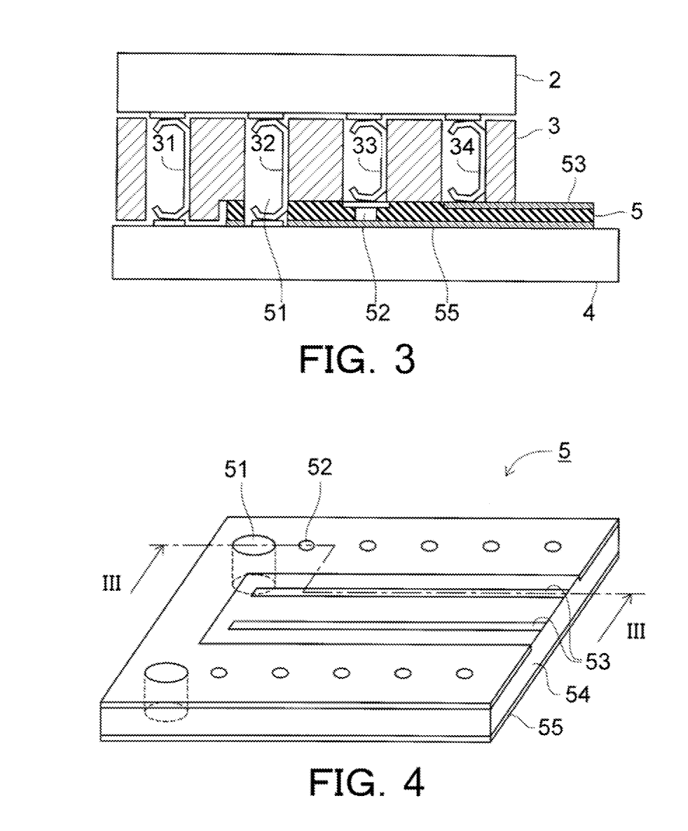

A specific example for realizing the connection between the IC 1 and the flexible cable 5 in the present embodiment will now be described. FIG. 3 illustrates a magnified view of a cross section of the portion enclosed by a dotted line illustrated in FIG. 2 in the first embodiment. FIG. 4 is a perspective view of the flexible cable 5. FIG. 3 is a cross-sectional view taken along line III-III of FIG. 4.

First, the flexible cable 5 is described with reference to FIG. 4. As illustrated in FIG. 4, the flexible cable 5 has a micro strip line structure in which signal lines 53 through which the electric signal from the IC 1 passes are formed on the upper surface of a dielectric substrate 54 that has a ground pattern 55 formed on the lower surface thereof. A high-speed electric signal passes through the flexible cable 5, which functions as a transmission line with a characteristic impedance of, for example, 50Ω. Note that FIG. 4 illustrates the case in which the electric signal from the IC 1 is a differential signal and a pair of signal lines 53 are provided.

The flexible cable 5 has through holes 51. The through holes 51 are holes extending through the flexible cable 5 in the thickness direction from the upper surface on which the signal lines 53 are formed to the lower surface on which the ground pattern 55 is formed. The flexible cable 5 has vias 52 provided thereon, and also has a ground pattern formed on the upper surface thereof on which the signal lines 53 are formed.

Referring to FIG. 3, a first embodiment will now be described. The IC socket 3 (shaded area) includes a plurality of types of pin formed as springs. A pin 31 provided on a surface in contact with the substrate 4 connects a pad of the IC package 2 to a pad of the substrate 4. Three types of pins 32, 33, and 34 are provided on a surface that is in contact with the flexible cable 5 and that is formed with a step, corresponding to the thickness of the flexible cable 5, between itself and the surface in contact with the substrate 4. The pin 32, extending through the corresponding through hole 51 of the flexible cable 5, connects a pad of the IC package 2 to a pad of the substrate 4. The pin 33, in contact with the corresponding via 52, connects a ground pad of the IC package 2 to the ground pattern 55 of the flexible cable 5. The pin 34, in contact with the signal line 53, transmits the electric signal from the IC 1 output from the IC package 2 over the flexible cable 5.

The flexible cable 5, which is positioned in such a manner as to be sandwiched between the IC socket 3 and the substrate 4, is pressed toward the substrate 4 side by the pins 33 and 34 provided on the IC socket 3. In this case, it is necessary to perform positioning of the flexible cable 5. In the first embodiment with the configuration described above, the IC package 2 and the IC socket 3 are pressed from above, thereby positioning the flexible cable 5 using the pin 32 and the through hole 51, and signal connection and the like are made using the pins 33 and 34. This configuration realizes connection of the IC 1 to the flexible cable 5 without deterioration of the high-frequency characteristics, while reducing the number of connection portions.

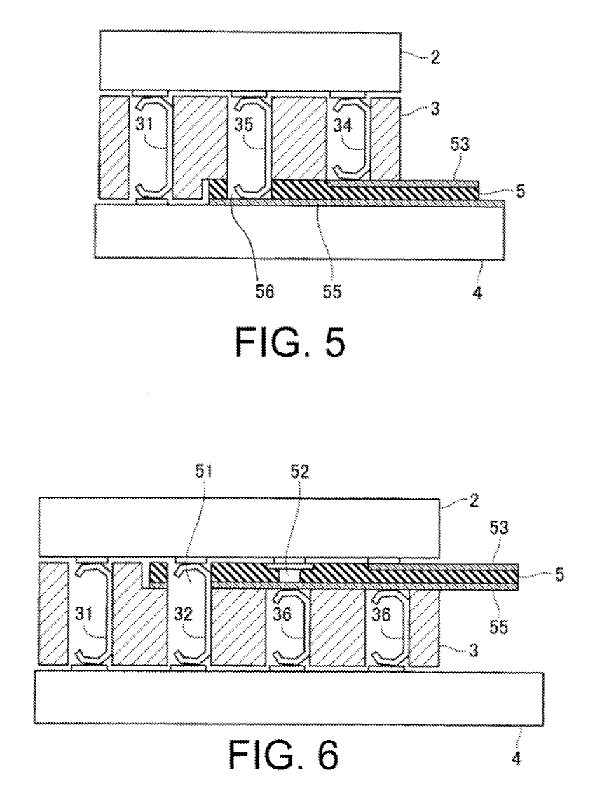

FIG. 5 is a magnified view of a cross section of a second embodiment. In the second embodiment, the flexible cable 5 as illustrated in FIG. 5 includes, instead of the through hole 51 in FIG. 3, an opening 56 for exposing the ground pattern 55 formed on the lower surface, the opening 56 extending through the upper surface having the signal lines 53 formed thereon. A pin 35 provided on a surface of the IC socket 3 in contact with the flexible cable 5 is in contact with the ground pattern 55 exposed through the opening 56, thereby connecting the ground pad of the IC package 2 to the ground pattern 55 of the flexible cable 5. In the second embodiment, the flexible cable 5 is positioned using the pin 35 and the opening 56. In other words, the pin 35 has functions of both ground connection and positioning.

When focusing on the ground connection made by the IC socket 3 in the first embodiment illustrated in FIG. 3, there are two discontinuous portions, at which potential electrical reflection may be caused, between the pin 33 and the via 52 and between the via 52 and the ground pattern 55, since the connection is through the via 52. On the other hand, in the second embodiment, there is only a single discontinuous portion between the pin 35 and the ground pattern 55, and hence, deterioration of the high-frequency characteristics may be further reduced.

The rest of the points are the same as those of the first embodiment. Accordingly, components in FIG. 5 corresponding to those in FIG. 3 are denoted by the same references, and the description thereof is omitted. The configuration of the second embodiment also enables connection of the IC 1 to the flexible cable 5 without deterioration or with a little deterioration of the high-frequency characteristics, while reducing the number of connection portions.

FIG. 6 is a magnified view of a cross section of a third embodiment. In the first and second embodiments, the IC socket 3 has a step corresponding to the thickness of the flexible cable 5 provided on the surface thereof in contact with the substrate 4. On the other hand, as illustrated in FIG. 6, the IC socket 3 in the third embodiment has a step corresponding to the thickness of the flexible cable 5 on a side thereof opposite the surface in contact with the substrate 4, in other words, on the surface on which the IC package 2 is mounted.

Two types of pins 32 and 36 of the IC socket 3 are provided on a surface that is in contact with the flexible cable 5. A step corresponding to the thickness of the flexible cable 5 is formed on a side of the surfaces of the IC socket 3, on which the IC package 2 is mounted. Similarly to the first embodiment, the pin 32, extending through the through hole 51 of the flexible cable 5, connects a pad of the IC package 2 to a pad of the substrate 4. The pins 36, in contact with the ground pattern 55, connect ground pads of the substrate 4 to the ground pattern 55 of the flexible cable 5. The ground pattern 55 is connected to the ground pad of the IC package 2 through the via 52. The signal lines 53 are in contact with the signal pads of the IC package 2. This allows connection for the electric signal from the IC 1 output from the IC package 2 to be made.

The rest of the points are the same as those of the first and second embodiments. Accordingly, components in FIG. 6 corresponding to those in FIGS. 3 and 5 are denoted by the same reference symbols, and the description thereof is omitted. In the third embodiment, the flexible cable 5, which is positioned in such a manner as to be sandwiched between the IC socket 3 and the IC package 2, is pressed toward the IC package 2 side by the pins 36 provided on the IC socket 3. Also in this case, the flexible cable 5 is positioned using the pin 32 and the through hole 51. The configuration of the third embodiment also enables connection of the IC 1 to the flexible cable 5 without deterioration or with a little deterioration of the high-frequency characteristics, while reducing the number of connection portions.

As described above in detail, according to the first to third embodiments, the electric signal generated by the IC 1 output from the IC package 2 is transmitted over the flexible cable 5 having good high-frequency characteristics without passing through the substrate 4. Similarly, the IC 1 may receive signals through the flexible cable 5. This allows the number of connection portions to be decreased and the IC 1 to be connected to the flexible cable 5 via the IC package 2 without deterioration or with a little deterioration of the high-frequency characteristics. Hence, the waveform of the signal from the IC 1 is prevented from deteriorating and the IC 1 may receive the signals prevented from deteriorating. In addition, the flexible cable 5 may be arranged accurately by being positioned using the pin 32 and the through hole 51, or using the pin 35 and the opening 56.

By connecting the IC package 2 to the substrate 4 and the flexible cable 5 using only the IC socket 3, the mounting space 15 in FIG. 1 may be reduced according the embodiments 1 to 3. Hence, cost reduction is realized owing to a reduction in the area of the substrate and the number of components.

As described above, the embodiments according to the present invention may become possible to mount a space-saving optical interconnect module which leads to prevent the increase of deterioration of electric signals in a system such as a server system in which introduction of optical interconnect technology has been needed in accordance with increased speed and/or increased transfer rate of electric signals.

Note that the present invention is not limited to the embodiments described above, and various improvements or modifications are possible within the scope of the invention.

For example, although an example of connection using the flexible cable 5 has been described in the embodiments, the present invention may be applied to an optical interconnect module that uses a printed circuit substrate (rigid substrate) having good high-frequency characteristics, instead of the flexible cable 5.

In addition, the IC socket 3 may be made to connect the IC package 2 to three or more substrates.

In the first and third embodiments, the pin 32 that extends through the through hole 51 and positions the flexible cable 5 connects a pad of the IC package 2 and a pad of the substrate 4. However, not limited to this, the pin 32 may be used only for positioning and not for connection.

Note that the flexible cable 5 is an example of another substrate; the pin 31 is an example of a first pin; the pins 33 to 36 are examples of second pins; the pin 32 is an example of a third pin; the pin 34 is an example of a signal pin; and the pin 35 is an example of a ground pin.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A substrate comprising:
a base substrate;
a socket that has a step, the step having a first surface and a second surface, the socket being electrically coupled with the base substrate at the first surface; and
a connection substrate disposed between the second surface and the base substrate, the connection substrate being electrically coupled with the socket at the second surface.

2. The substrate according to claim 1, further comprising an integrated circuit package mounded on the socket, wherein the socket has
a mounting surface that mounts the integrated circuit package,
a first pin that is electrically coupled with the base substrate at the first surface, and
a second pin that is electrically coupled with the connection substrate at the second surface, and
the second pin pushes the connection substrate toward the base substrate.

3. A substrate comprising:
a base substrate;
an integrated circuit package;
a socket that has a step, the step having a first surface a second surface, the socket being electrically coupled with the integrated circuit package at the first surface; and
a connection substrate disposed between the second surface and the integrated circuit package, the connection substrate being electrically coupled with the socket at the second surface.

4. The substrate according to claim 3, wherein the socket has
a third surface that is electrically coupled with the base substrate,
a first pin that is electrically coupled with the integrated circuit package at the first surface, and
a second pin that is electrically coupled with the connection substrate at the second surface,
wherein the second pins push the connection substrate toward the integrated circuit package.

5. The substrate according to claim 2, wherein the connection substrate has
a signal line that allows a signal to flow, the signal being sent from the integrated circuit package, the signal line being formed on one of surfaces of the connection substrate,
a ground formed on the other of the surfaces, and
a through hole that passes through the connection substrate in the direction of a thickness of the connection substrate, and
the socket has a third pin passing through the through hole, the third pin and the through hole being capable of positioning the connection substrate.

6. The substrate according to claim 4, wherein the connection substrate has
a signal line that allows a signal to flow, the signal sent from the integrated circuit package, the signal line formed on one of surfaces of the connection substrate,
a ground formed on the other of the surfaces, and
a through hole that passes through the connection substrate in the direction of a thickness of the connection substrate, and
the socket has a third pin passing through the through hole, the third pin and the through hole being capable of positioning the connection substrate.

7. The substrate according to claim 2, wherein the connection substrate has
a signal line that allows a signal to flow, the signal sent from the integrated circuit package, the signal line formed on one of surfaces of the connection substrate,
a ground formed on the other of the surfaces, and
an opening facing the ground, the opening formed in the direction of a thickness of the connection substrate,
the second pin include
a signal pin that contacts with the signal line, and
a ground pin that contacts with the ground,
wherein the ground pin and the opening are capable of positioning the connection substrate.

8. The substrate according to claim 4, wherein the connection substrate has
a signal line that allows a signal to flow, the signal sent from the integrated circuit package, the signal line formed on one of surfaces of the connection substrate,
a ground formed on the other of the surfaces, and
an opening facing the ground, the opening formed in the direction of a thickness of the connection substrate,
the second pins include
a signal pin that contacts with the signal line, and
a ground pin that contacts with the ground,
wherein the ground pin and the opening are capable of positioning the connection substrate.

9. The substrate according to claim 5, wherein the connection substrate is made from a dielectric material, and the ground and the signal line configure a micro strip line.

10. The substrate according to claim 7, wherein the connection substrate is made from a dielectric material, and the ground and the signal line configure a micro strip line.

11. A socket for mounting with an integrated circuit package comprising:
a first surface, and
a second surface, the second surface being formed on a side of the socket,
wherein a step is formed between the first and the second surfaces, and each of the first and the second surface is connected to respective substrates.

12. The socket according to claim 11, wherein the side faces the integrated circuit package.

13. The socket according to claim 11, wherein the side is a rear of a surface facing the integrated circuit package.
